(19) United States
(12) Patent Application Publication
(10) Pub. No.: US 2026/0147969 A1
(43) Pub. Date: May 28, 2026

(54) DESIGN METHOD OF SEMICONDUCTOR DEVICE

(71) Applicant: Samsung Electronics Co., Ltd., Suwon-si (KR)

(72) Inventors: Youngjin Ju, Suwon-si (KR); Dongsub Yoon, Suwon-si (KR); Hyojin Choi, Suwon-si (KR); Thai Hoang Nguyen, Suwon-si (KR)

(21) Appl. No.: 19/327,745

(22) Filed: Sep. 12, 2025

(30) Foreign Application Priority Data
Nov. 27, 2024 (KR) 10-2024-0171905

(51) Int. Cl. G06F 30/31

(52) U.S. Cl. CPC G06F 30/31

(57) ABSTRACT

An example method of designing a semiconductor device includes: generating a training dataset and a mapping dataset using preset data; training a neural network model extracting features of a standard cell included in a library using the training dataset; inputting a target standard cell into the neural network model to extract features of the target standard cell; selecting a configuration file based on the features of the target standard cells extracted by the neural network model and the mapping dataset; and performing characterization of the target standard cell using an Electronic Design Automation (EDA) tool to which the selected configuration file is applied.

### CROSS-REFERENCE TO RELATED APPLICATION

This application claims the benefit under 35 USC 119(a) of Korean Patent Application No. 10-2024-0171905 filed in the Korean Intellectual Property Office on Nov. 27, 2024, the entire disclosure of which is incorporated herein by reference.

### BACKGROUND

In a process of manufacturing a semiconductor device, a design and verification process of circuits included in the semiconductor device may be automated by utilizing an electronic design automation (EDA) tool. For example, the EDA tool may extract features of each of standard cells by applying a rule-based algorithm to standard cells included in a library. As described above, by applying a rule-based algorithm, a simulation required for characterization of the standard cell may be determined based on the features extracted from each of the standard cells. However, with a rule-based algorithm, the rules should be manually updated to match the standard cells, for example when a new standard cell is added to the library. This process may consume a large amount of time and may also result in errors, which can reduce the efficiency and accuracy of semiconductor design.

### SUMMARY

The present disclosure relates to a method of designing a semiconductor device that can automatically select a configuration file for a characterization operation of a target standard cell, by extracting features of a target standard cell using a neural network model, and mapping a configuration file corresponding to the extracted features of the target standard cell.

In some implementations, a method of designing a semiconductor device includes: generating a training dataset and a mapping dataset using preset data; training a neural network model extracting features of a standard cell included in a library using the training dataset; inputting a target standard cell into the neural network model to extract features of the target standard cell; selecting a configuration file based on the features of the target standard cell and the mapping dataset by the neural network model; and performing characterization of the target standard cell using an Electronic Design Automation (EDA) tool to which the selected configuration file is applied.

In some implementations, a method of designing a semiconductor device includes: converting information of a target standard cell to be suitable for input of a neural network model; extracting feature combinations of the target standard cell from the converted information of the target standard cell using the neural network model; selecting a configuration file corresponding to the feature combinations of the target standard cell using the neural network model; and performing characterization of the target standard cell using an Electronic Design Automation (EDA) tool to which the selected configuration file is applied.

In some implementations, a method of designing a semiconductor device includes: converting a plurality of components included in a target standard cell, a schematic circuit, into a plurality of nodes, respectively; representing a plurality of node features included in each of the plurality of nodes as a vector; representing a connection relationship between the plurality of components as an adjacent matrix; inputting the plurality of node features converted from the information of the target standard cell to be suitable for input of the neural network model and the adjacency matrix into the neural network model; and outputting feature combinations of the target standard cell based on the input plurality of node features and the adjacent matrix by the neural network model, wherein the plurality of node features include information regarding whether each of the plurality of components is a port, a net, a transistor, and a transistor pin, and include information regarding a port type if each of the plurality of components is a port, information regarding a transistor type if each of the plurality of components is a transistor, and information regarding a transistor pin type if each of the plurality of components is a transistor pin.

### BRIEF DESCRIPTION OF THE DRAWINGS

Example implementations will be more clearly understood from the following detailed description, taken in conjunction with the accompanying drawings.

FIG. 1 is a flow chart illustrating an example of a method of designing a semiconductor device.

FIG. 2 is a flow chart illustrating an example of a method of designing a semiconductor device.

FIGS. 3, 4, 5A, and 5B are drawings illustrating a portion of examples of a method of designing a semiconductor device.

FIG. 6 is a drawing illustrating a portion of an example of a method of designing a semiconductor device.

FIG. 7 is a drawing illustrating a portion of an example of a method of designing a semiconductor device.

FIG. 8 is a drawing illustrating a portion of an example of a method of designing a semiconductor device.

FIGS. 9A and 9B are drawings illustrating a portion of examples of a method of designing a semiconductor device.

FIG. 10 is a drawing illustrating an example of a training process of a neural network model.

FIG. 11 is a drawing illustrating an example of a method of designing a semiconductor device.

### DETAILED DESCRIPTION

Hereinafter, example implementations will be explained in detail with reference to the accompanying drawings.

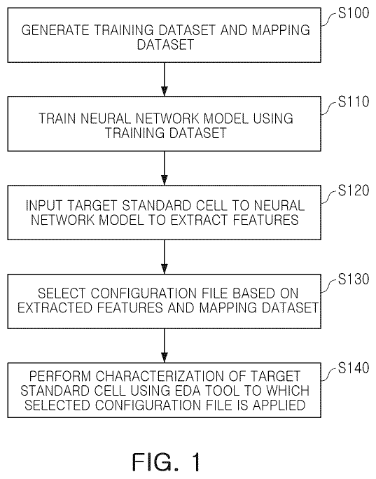

FIG. 1 is a flow chart illustrating an example of a method of designing a semiconductor device.

An Electronic Design Automation (EDA) tool may refer to a software tool used for semiconductor design and electronic circuit design. An EDA tool may be used to automate integrated circuit (IC) design, printed circuit board (PCB) design, circuit simulation, physical layout, and the like, and to efficiently process various electronic design operations. The EDA tool may shorten the time for semiconductor design, increase the accuracy, and improve the design quality of complex semiconductor systems.

Characterization of a standard cell may be a process of precisely measuring and evaluating the electrical performance of each standard cell during semiconductor design and manufacturing processes. Characterization of a standard cell may include an operation of extracting information such as timing information of signals input and output to the standard cell, power consumption, number of transistors, cell size, capacitance, and the like. Characterization of a standard cell may be performed by an EDA tool, and a more precise and reliable semiconductor device may be designed through the characterization of a standard cell.

A configuration file may be used to set and perform an EDA tool used in the semiconductor design process. For example, the EDA tool may include a characterization tool for performing characterization of a standard cell, and the configuration file can be used to set and perform the characterization tool. A design environment may be set by the configuration file, and the configuration file can include information regarding a path of a library to be used, technology node information, constrains, timing, power settings, and the like, may be included in the configuration file. The EDA tool may reflect specific design requirements and environments using the configuration file, and generate optimized results. The configuration file may be configured differently depending on the type of EDA tool and the design project.

For the characterization tool to perform characterization on a standard cell, it should first be determined which simulations should be performed on the standard cell. In addition, to determine which simulations should be performed on the standard cell, the operation of extracting features of the standard cell may need to be performed first. In some implementations, the features of a standard cell may include topological structure, function, timing arc, and the like. A rule-based algorithm can be applied to the operation of extracting the features of a standard cell, but this method can take a lot of time and reduce the efficiency of semiconductor design.

In some implementations, the features of a standard cell may be extracted by using a trained neural network model. A neural network model is a type of artificial intelligence, and may be used to learn and predict complex patterns from large-scale datasets. The neural network model may be trained based on preset data generated by a plurality of standard cells having been characterized using a characterization tool. For example, the neural network model may be trained to extract features from each of the plurality of standard cells.

Based on the preset data of the plurality of standard cells, a configuration file corresponding to the features extracted from the standard cells may be mapped. In some implementations, a configuration file that is mapped to features extracted from a standard cell may be a configuration file applied to an EDA tool in a characterization operation for the standard cell.

Once a target standard cell to be added to a library as a new standard cell is determined, the features of the target standard cell may be extracted using the previously trained neural network model. The configuration file mapped to the features of the target standard cell extracted from the neural network model is applied to the EDA tool, and the characterization operation for the target standard cell can be performed using the EDA tool. Therefore, the operation of selecting and/or setting the configuration file of the EDA tool prior to the characterization operation can be automated based on the neural network model, which can improve the efficiency and accuracy of semiconductor design.

In some implementations, a training dataset and a mapping dataset can be generated using preset data (S100). In some implementations, the preset data may include a plurality of standard cells having been characterized using an EDA tool, configuration files applied to the EDA tool to characterize the plurality of standard cells using the EDA tool, and performance results of characterizing the plurality of standard cells using the EDA tool. A designer can collect preset data to generate a training dataset for training a neural network model, and a mapping dataset in which feature combinations and configuration files are mapped.

In some implementations, a neural network model may be trained using a training dataset (S110). A designer may train a neural network model extracting features of a standard cell using a training dataset, and the standard cell is included in a library. In some implementations, the neural network model may be a Graph Neural Networks (GNN) model or an Artificial Neural Networks (ANN) model. In some implementations, the GNN model may be at least one of a Graph Convolutional Network (GCN) model, a Graph Attention Network (GAT) model, and a Graph Isomorphism Network (GIN) model. In some implementations, the neural network model may be a structure that is serially connected with a GNN model and a Graph Transformer model.

In some implementations, a target standard cell may be input into a neural network model to extract features (S120). The target standard cell may be a standard cell that is to be added to a library as a new standard cell. The target standard cell may be a standard cell that is not included in a library. The trained neural network model may predict and extract features of a target standard cell, when a new target standard cell is input. In some implementations, the target standard cell may be a standard cell included in a Dynamic Random Access Memory (DRAM) or a standard cell included in a non-volatile memory.

The method of designing a semiconductor device according to some implementations may also be applied to a standard cell not having a complete CMOS structure, a DRAM implemented with a high degree of integration and/or a non-volatile memory. For example, the target standard cell may have a structure in which an input terminal or an output terminal of the target standard cell and a transmission gate are directly connected. The trained neural network model may extract the features of the target standard cell even if the target standard cell not having a complete CMOS structure is input.

In a method of designing a semiconductor device according to some implementations, a configuration file may be selected based on features extracted from a target standard cell and a mapping dataset using the trained neural network model (S130). The mapping dataset may include information regarding a configuration file mapped to features extracted from each of a plurality of standard cells. Features of a target standard cell may be extracted through a neural network model, and a configuration file corresponding to the features of the extracted target standard cell may be mapped using a mapping dataset. In some implementations, the configuration file mapped to the features extracted from one target standard cell may be a configuration file applied to an EDA tool in the characterization operation for at least one standard cell among a plurality of standard cells used for training the neural network model.

In a method of designing a semiconductor device according to some implementations, an EDA tool to which a selected configuration file is applied may be used to perform characterization of a target standard cell (S140). To perform characterization of a target standard cell, selection of a configuration file should be performed in advance, and to select a configuration file, an operation of extracting features of the target standard cell can be performed in advance. The configuration file mapped to the features of the target standard cell extracted from the neural network model may be applied to an EDA tool, and a characterization operation for the target standard cell may be performed using the EDA tool. The target standard cell for which the characterization operation has been performed can be added to a library.

In some implementations, by automating the task of selecting and/or setting a configuration file of an EDA tool prior to a characterization operation based on a neural network model, the time for designing a semiconductor device may be shortened, and an efficient method for designing a semiconductor device may be provided.

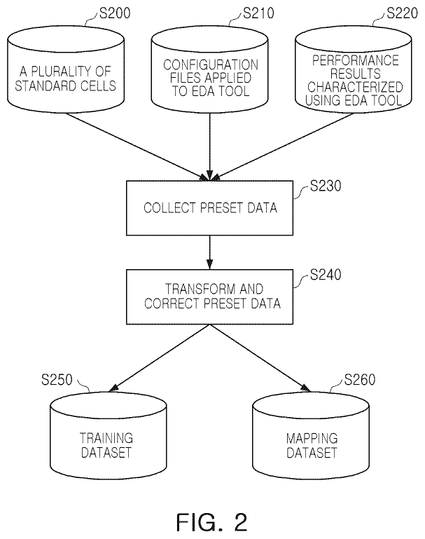

FIG. 2 is a flow chart illustrating an example of a method of designing a semiconductor device.

In a method of designing a semiconductor device according to some implementations, preset data may be collected from a plurality of standard cells (S230). The preset data may include a plurality of standard cells having been characterized using an EDA tool (S200), configuration files applied to the EDA tool to characterize the plurality of standard cells using the EDA tool (S210), and performance results of characterizing the plurality of standard cells using the EDA tool (S220).

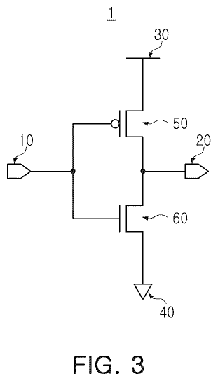

In a method of designing a semiconductor device according to some implementations, preset data collected from a plurality of standard cells may be converted and corrected (S240). Before inputting preset data as training data of a neural network model, preset data may be converted and corrected so as to be suitable for input into a neural network model. In some implementations, the neural network model may be a GNN model, and preset data to be used as training data for the neural network model may be converted into a graph. The process of converting preset data into a graph is described in detail with reference to FIGS. 3, 4, 5A, and 5B below.

In some implementations, feature combinations extracted from a portion of standard cells may have a plurality of configuration files that can be applied to an EDA tool. To improve the training performance of a neural network model, when the plurality of configuration files may be applied to an EDA tool for a single feature combination, the preset data may be corrected so that a single configuration file is applied to the EDA tool for a single feature combination. By correcting preset data before using the same as training data for a neural network model, the training ability of the neural network model may be improved.

In a method of designing a semiconductor device according to some implementations, a training dataset (S250) and a mapping dataset (S250) may be generated based on preset data. The training dataset (S250) may be training data used to train a neural network model. The training dataset (S250) may include data that has been converted and corrected to be suitable for input to a neural network model by converting and correcting preset data generated by a plurality of standard cells. The mapping dataset (S260) may include data to which a configuration file corresponding to features extracted from standard cells is mapped.

A method of designing a semiconductor device according to some implementations may extract features of a standard cell using a trained neural network model. To train a neural network model used in a method of designing a semiconductor device, a training dataset (S250) and a mapping dataset (S260) can be generated, by collecting preset data obtained from a plurality of standard cells and converting and correcting the preset data. By generating a training dataset (S250) and a mapping dataset (S260), a neural network model may be trained and used, and a process of extracting features of a target standard cell through the neural network model and mapping a configuration file corresponding thereto may be automated, thereby shortening the time for designing a semiconductor device and providing an efficient method for designing a semiconductor device.

FIGS. 3, 4, 5A, and 5B are drawings illustrating a portion of examples of a method of designing a semiconductor device.

In a method of designing a semiconductor device according to some implementations, a standard cell may be converted into a graph to be suitable as an input of a neural network model. In some implementations, preset data of a plurality of standard cells used in a training dataset may be converted into a graph. Alternatively, the information of the target standard cell input to the trained neural network model may be converted into a graph.

Referring to FIG. 3, a standard cell 1 may be converted into a graph. In some implementations, the standard cell 1 may be an inverter standard cell. The inverter standard cell 1 may include a plurality of components such as an input terminal 10, an output terminal 20, a VDD 30, a GND 40, a PMOS transistor 50, and an NMOS transistor 60.

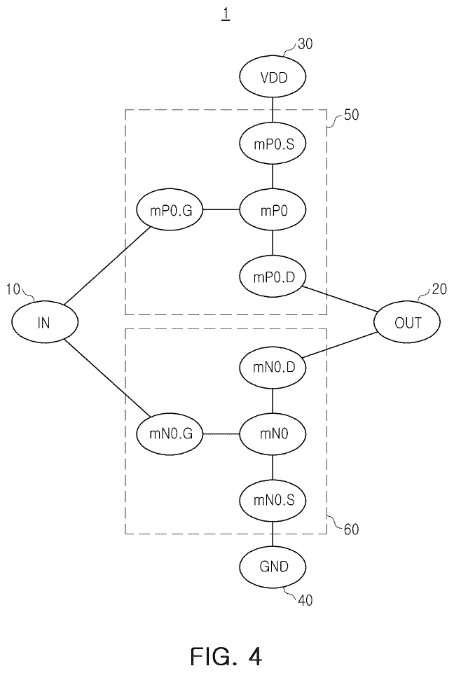

In a method of designing a semiconductor device according to some implementations, a plurality of components included in the standard cell 1 may be converted into a plurality of nodes. Referring to FIGS. 3 and 4, a plurality of components included in the inverter standard cell 1 illustrated in FIG. 4, such as an input terminal 10, an output terminal 20, a VDD 30, a GND 40, a PMOS transistor 50, and an NMOS transistor 60, may be converted into a plurality of nodes. For example, the PMOS transistor 50, which is one of the plurality of components, may include a gate (mP0.G), a source (mP0.S), and a drain (mP0.D). Referring to FIG. 4, each of the gate (mP0.G), the source (mP0.S), and the drain (mP0.D) included in the PMOS transistor 50 may be converted into a node. The NMOS transistor 60, which is one of the plurality of components, may also include a gate (mN0.G), a source (mN0.S), and a drain (mN0.D). Referring to FIG. 4, the gate (mN0.G), the source (mN0.S), and the drain (mN0.D) included in the NMOS transistor 60 may be converted into a node.

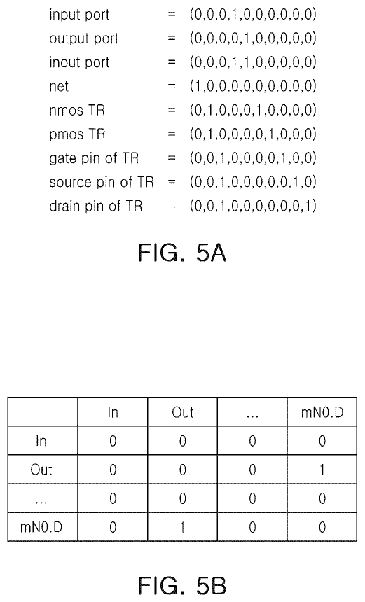

A method of designing a semiconductor device according to some implementations may include representing a plurality of node features included in each node of a plurality of nodes as a vector. Referring to FIG. 5A, a plurality of node features may be represented as a vector of N bits, where N is a natural number. In some implementations, the plurality of node features may include first information indicating each component of the plurality of components is a port, a net, a transistor, or a transistor pin, and include second information indicating (i) a port type based on each component of the plurality of components being a port, (ii) a transistor type based on each component of the plurality of components being a transistor, or (iii) a transistor pin type based on each component of the plurality of components being a transistor pin.

Referring to FIG. 5A, each of the plurality of node features according to some implementations may be represented as a vector of 10 bits. First three bits of the vectors of 10 bits may include the first information. For example, the first three bits could be [000] if each of the components is a port, [100] if each of the components is a net, [010] if each of the components is a transistor, and [001] if each of the components is a transistor pin.

Two bits from among each of the vectors of 10 bits may include the second information. For example, if the two bits representing a port type are [00], the component may not be a port. As described above, from among the vectors of 10 bits representing a plurality of node features, if the component is not a port, all bits related to the port may have a value [0], and if the component is not a transistor, all bits related to the transistor may have a value [0].

Referring to FIGS. 4 and 5A, the input terminal 10 illustrated in FIG. 4 may have a vector value of an input port illustrated in FIG. 5A, and the output terminal 20 illustrated in FIG. 4 may have a vector value of an output port illustrated in FIG. 5A. An mP0 of the PMOS transistor 50 illustrated in FIG. 4 may have a vector value of the pmos TR illustrated in FIG. 5A, and a gate (mP0.G) of the PMOS transistor 50 may have a vector value of a gate pin of TR. However, the vector illustrated in FIG. 5A is only an example of converting information of standard cells into a graph, and an example implementation thereof is not limited thereto. According to some implementations, an order in which information of standard cells is represented as a vector or the number of bits used may be different.

A method of designing a semiconductor device according to some implementations may include representing a connection relationship between a plurality of nodes as an adjacency matrix. Referring to FIG. 5B, the adjacency matrix may be a matrix representing a connection between a plurality of nodes. In some implementations, the adjacency matrix may be a matrix representing 1 when nodes are connected and 0 when nodes are not connected. Referring to FIGS. 4 and 5B, since an output terminal 20 and a drain (mN0.D) of the NMOS transistor 60 are connected, the adjacency matrix may have a value of 1, and since the output terminal 20 and the input terminal 10 are not connected, the adjacency matrix may have a value of 0.

In some implementations, the method of designing a semiconductor device may include converting preset data and/or a target standard cell obtained from a plurality of standard cells into a graph in a form suitable for input to a neural network model. By converting input data input to a neural network model in advance, the time required to design a semiconductor device may be shortened, thereby an efficient method of designing the semiconductor device.

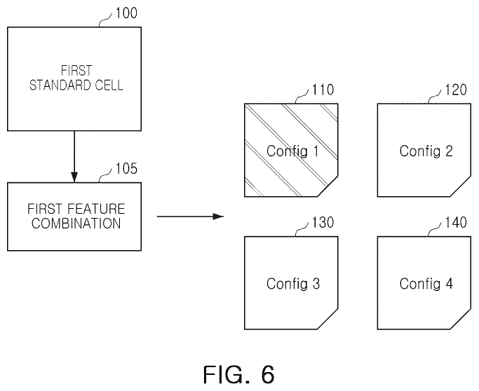

FIG. 6 is a drawing illustrating a portion of an example of a method of designing a semiconductor device.

A method of designing a semiconductor device according to some implementations may include an operation of generating a mapping dataset. In the operation of generating a mapping dataset, there may be a plurality of configuration files that can be applied to an EDA tool among feature combinations extracted from some standard cells among a plurality of standard cells. When the plurality of configuration files may be applied to an EDA tool for a single feature combination, the mapping dataset may be corrected so that a single configuration file corresponds to a single feature combination.

Referring to FIG. 6, a first feature combination 105 may be extracted from a first standard cell 100, one of a plurality of standard cells having been characterized using an EDA tool. To characterize the first standard cell 100 with an EDA tool, a plurality of configuration files may be applied to the EDA tool. The plurality of configuration files may include a first configuration file 110, a second configuration file 120, a third configuration file 130, and a fourth configuration file 140. To improve the training performance of a neural network model, a mapping dataset may be corrected so that only the first configuration file 110 is mapped to the first feature combination 105.

In the operation of generating a mapping dataset according to some implementations, when a plurality of configuration files may be applied to an EDA tool to characterize one standard cell included in a library using the EDA tool, the mapping dataset may be corrected so that only a single configuration file is mapped. The mapping dataset may be corrected so that a single configuration file is mapped to a single feature combination, so that the training performance of a neural network model using a training dataset and a mapping dataset may be improved, and the accuracy and efficiency of a method of designing a semiconductor device using a neural network model may be improved.

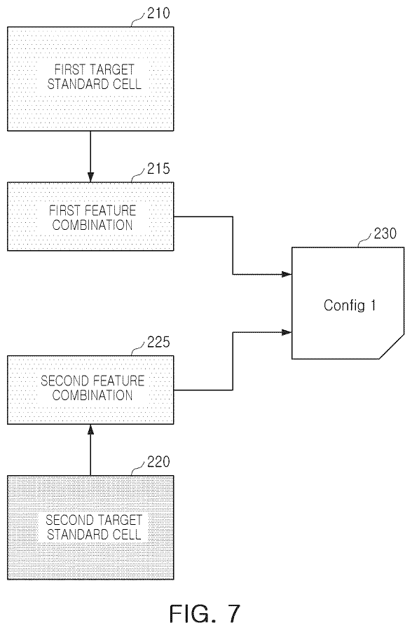

FIG. 7 is a drawing illustrating a portion of an example of a method of designing a semiconductor device.

In some implementations, when feature combinations extracted from different standard cells match, a neural network model may be trained to select a single configuration file for different standard cells. For example, a first standard cell and a second standard cell may be input to a neural network model. If the first feature combination of the first standard cell and the second feature combination of the second standard cell match, the neural network model may be trained to select a single configuration file.

Referring to FIG. 7, a first target standard cell 210 and a second target standard cell 220 may be input to a trained neural network model. When the first target standard cell 210 is input to the neural network model, a first feature combination 215 may be output, and when the second target standard cell 220 is input, a second feature combination 225 may be output. In some implementations, the method of designing a semiconductor device may include a process of converting information of the first target standard cell 210 and the second target standard cell 220 into a graph so that the first target standard cell 210 and the second target standard cell 220 are suitable for input into a neural network model.

In some implementations, the first feature combination 215 may include at least two or more first features, and the second feature combination 225 may include at least two or more second features. For example, the first feature combination 215 and the second feature combination 225 may include at least two of a topology structure, a function, and a timing arc. When the first features included in the first feature combination 215 and the second features included in the second feature combination 225 all match, the trained neural network model may select one configuration file 230 for the first target standard cell 210 and the second target standard cell 220.

In some implementations, by training a neural network model so that one configuration file 230 is mapped when feature combinations extracted from different target standard cells are the same, the time for designing a semiconductor device can be shortened and an efficient method of designing a semiconductor device can be provided.

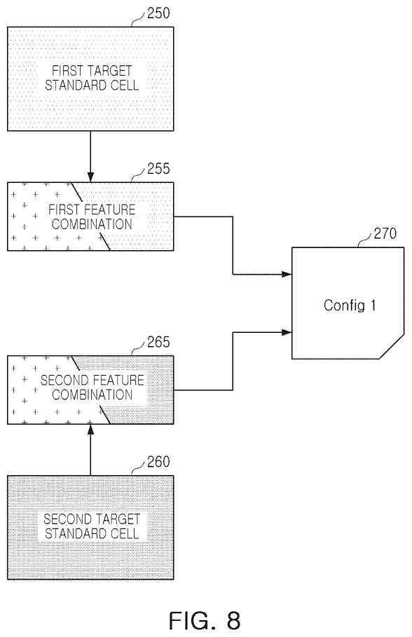

FIG. 8 is a drawing illustrating a portion of an example of a method of designing a semiconductor device.

In some implementations, a neural network model may be trained to select one configuration file for different standard cells when a portion of the feature combinations extracted from different standard cells match. For example, a first standard cell and a second standard cell may be input to a neural network model. If the first feature combination of the first standard cell and the second feature combination of the second standard cell are partially the same, the neural network model may be trained to select one configuration file.

Referring to FIG. 8, a first target standard cell 250 and a second target standard cell 260 may be input to a trained neural network model. When the first target standard cell 250 is input to the trained neural network model, a first feature combination 255 may be output, and when the second target standard cell 260 is input, a second feature combination 265 may be output. In some implementations, the process may include a process of converting information of the first target standard cell 250 and the second target standard cell 260 into graphs so that the first target standard cell 250 and the second target standard cell 260 are suitable for input into a neural network model.

The first feature combination 255 may include at least two first features, and the second feature combination 265 may include at least two second features. When a portion of the first features included in the first feature combination 255 and a portion of the second features included in the second feature combination 265 match, the trained neural network model can select one configuration file 270 for the first feature combination 255 and the second feature combination 265.

In some implementations, by training a neural network model so that one configuration file 270 is mapped when a portion of the feature combinations extracted from different standard cells match, the time for designing a semiconductor device may be shortened and an efficient design method for a semiconductor device may be provided.

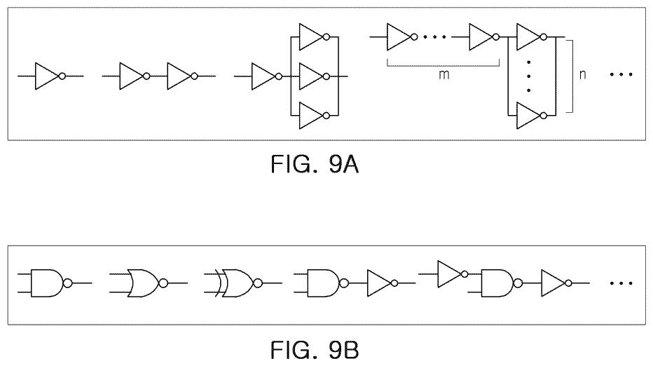

FIGS. 9A and 9B are drawings illustrating a portion of examples of a method of designing a semiconductor device.

In a method of designing a semiconductor device according to some implementations, a plurality of standard cells may be classified into a plurality of groups based on feature combinations. A plurality of the standard cells classified into one group may have different structures, but may be mapped to one configuration file. A plurality of the standard cells classified into one group may match a portion or all of the feature combinations.

Referring to FIGS. 9A and 9B, the neural network model may classify a plurality of standard cells into a plurality of groups by features. Referring to FIG. 9A, the plurality of standard cells consisting of inverters may be classified into a first group. Specifically, the first group may include standard cells connected in series or parallel with the one or more inverters. In some implementations, all or a portion of the feature combinations extracted from each of the standard cells included in the first group may match. The standard cells included in the first group may apply one configuration file to an EDA tool.

Referring to FIG. 9B, a second group may include standard cells formed by a combination of NAND, NOR, and inverter. In some implementations, standard cells included in the second group may be considered as having characteristics that do not match based on a logical function, but may be considered as having characteristics that match based on input vectors since the standard cells may be characterized using the same input vectors, and thus may be classified as one group. In some implementations, all or a portion of the feature combinations extracted from each of the standard cells included in the second group may match. The standard cells included in the second group may apply one configuration file to an EDA tool.

In some implementations, a plurality of standard cells may be classified into a plurality of groups based on feature combinations, and a neural network model may be trained to learn patterns and correlations of standard cells, feature combinations, and configuration files that are classified in one group. The trained neural network model may extract feature combinations of a new standard cell, and predict a configuration file corresponding to the extracted feature combinations.

By introducing the trained neural network model into a method of designing a semiconductor device according to some implementations, a process of extracting features of a target standard cell and selecting a configuration file to be applied to an EDA tool corresponding thereto can be automated, thereby providing a method of designing a semiconductor device with reduced time and improved performance.

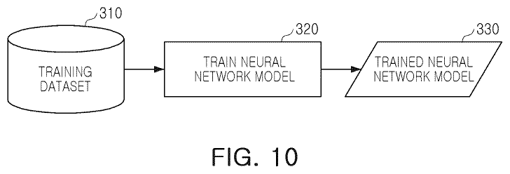

FIG. 10 is a drawing illustrating an example of a training process of a neural network model.

A method of designing a semiconductor device according to some implementations may generate a training dataset 310 based on preset data including a plurality of standard cells characterized using an EDA tool, configuration files applied to the EDA tool to characterize the plurality of standard cells using the EDA tool, and performance results of characterizing the plurality of standard cells using the EDA tool.

The training dataset 310 is training data for training a neural network model. When a standard cell is input into the neural network model, the neural network model can be trained to output feature combinations of the standard cells. In some implementations, the mapping dataset may be generated together with a training dataset 310, based on the preset data. The mapping dataset may map a configuration file corresponding to feature combinations output from the neural network model. In some implementations, the configuration file that is mapped to features extracted from a standard cell may be a configuration file applied to an EDA tool in a characterization operation for the standard cell.

In some implementations, the neural network model may be trained 320 using the training dataset 310. The neural network model extracting features of standard cells included in a library may be trained using the training dataset 310. By training the neural network model using the training dataset 310, when a new target standard cell not included in the library is input, the prediction ability and accuracy of the neural network model can be improved to extract feature combinations.

In some implementations, when the target standard cell is input, the trained neural network model 330 may extract and output features of the target standard cell. Once the target standard cell to be added as a new standard cell to the library is determined, the features of the target standard cell may be extracted using the trained neural network model 330. A configuration file mapped to the features of the target standard cell extracted from the trained neural network model 330 may be applied to an EDA tool, and characterization operation on the target standard cell may be performed using the EDA tool.

The trained neural network model 330 according to some implementations may extract features of the target standard cell, when a new target standard cell is input, and select a configuration file to be applied to an EDA tool corresponding thereto. By introducing a neural network model into a method of designing a semiconductor device according to some implementations, a process of extracting features of a target standard cell and selecting a configuration file to be applied to an EDA tool corresponding thereto may be automated, thereby providing a method of designing a semiconductor device having reduced time and improved performance.

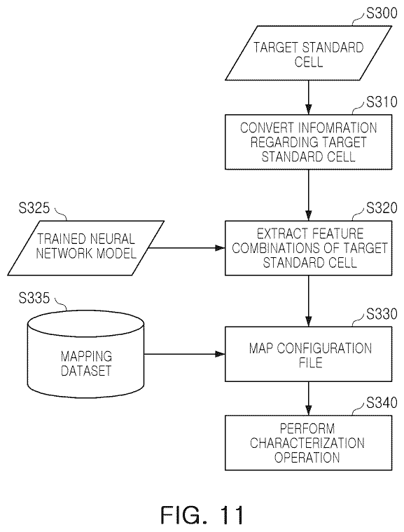

FIG. 11 is a drawing illustrating an example of a method of designing a semiconductor device.

A method of designing a semiconductor device according to some implementations may extract features of a target standard cell using a neural network model, and map a configuration file to be applied to an EDA tool based on the extracted features, thereby performing characterization of the target standard cell using an EDA tool to which the mapped configuration file is applied. A new target standard cell having been characterized may be added to a library.

In some implementations, information included in a target standard cell (S300) may be converted to be suitable as an input of a neural network model (S310). In some implementations, the target standard cell may be represented as a schematic circuit, and the target standard cell may include a plurality of components. The operation of converting information included in the target standard cell may include an operation of converting a plurality of components included in the target standard cell, which is a schematic circuit, into a plurality of nodes. The plurality of node features included in each of the plurality of nodes may be represented as vectors. In some implementations, the plurality of node features may include information regarding whether each of the plurality of components is a port, a net, a transistor, and a transistor pin, and may include information regarding a port type if each of the plurality of components is a port, and information regarding a transistor type and information regarding a transistor pin type if each of the plurality of components is a transistor. A connection relationship between the plurality of components may be represented by an adjacency matrix.

In some implementations, feature combinations of the target standard cell may be extracted (S320) using a trained neural network model (S325). Various features of target standard cells may be automatically extracted using the trained neural network model (S325). The neural network model may be trained based on preset data obtained from a plurality of different standard cells, so that when a new type of target standard cell is input to the neural network model, the neural network model may be trained to accurately identify and extract feature combinations of the target standard cell.

In some implementations, a configuration file corresponding to feature combinations extracted using a mapping dataset (S335) may be mapped (S330). Since the mapping dataset S335 includes information regarding feature combinations of a plurality of standard cells and corresponding thereto, an appropriate configuration file may be automatically mapped based on the feature combination extracted by the neural network model. A mapping process may be processed very quickly, which can effectively improve the efficiency and accuracy of the method of designing semiconductor devices compared to the existing method of manually identifying feature combinations and mapping configuration files.

In some implementations, the mapped configuration file may be applied to the EDA tool to perform a characterization operation of the target standard cell (S340). By performing the characterization operation of the target standard cell using the EDA tool, the performance, operating characteristics, and optimized design parameters of the target standard cell may be evaluated and verified in real time. Prior to performing the characterization operation of the target standard cell using an EDA tool, the process of extracting the features of the target standard cell may be automated using a neural network model, thereby shortening the time for a designer to design a semiconductor device and enabling the designer to design a semiconductor device accurately and efficiently.

As set forth above, according to some implementations, by training a neural network model to extract features of standard cells implemented as each of standard cells included in a library, and inputting a target standard cell to a trained neural network model, feature combinations of the target standard cell may be automatically extracted.

A configuration file corresponding to the extracted feature combinations of the target standard cell may be automatically mapped using a mapping dataset, and a characterization operation of the target standard cell may be performed by applying the mapped configuration file to an EDA tool.

Therefore, the process of extracting feature combinations and selecting a configuration file suitable for the feature combinations and applying the same to an EDA tool may be automated prior to performing the characterization operation of the target standard cell, thereby improving the efficiency of the method of designing a semiconductor device.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

The various advantages and effects of the present disclosure are not limited to the above-described content, and can be more easily understood through description of implementations of the present disclosure.

While some implementations have been illustrated and described above, it will be apparent to those skilled in the art that modifications and variations could be made without departing from the scope of the present disclosure as defined by the appended claims.

What is claimed is:

1. A method of designing a semiconductor device, comprising:
generating, based on preset data, a training dataset and a mapping dataset;
training, based on the training dataset, a neural network model to extract a plurality of features of a standard cell included in a library;
inputting a target standard cell into the neural network model and extracting a plurality of feature combinations of the target standard cell;
selecting, using the neural network model and based on the plurality of feature combinations of the target standard cell and the mapping dataset, a configuration file; and
applying the configuration file to an Electronic Design Automation (EDA) tool to perform characterization of the target standard cell.

2. The method of claim 1, wherein the preset data includes a plurality of standard cells, a plurality of configuration files, and a plurality of performance results, the plurality of configuration files being applied to the EDA tool to characterize the plurality of standard cells and to generate the plurality of performance results.

3. The method of claim 2, wherein generating the training dataset and the mapping dataset includes:
collecting the preset data from the plurality of standard cells;
converting the preset data into a graph;
generating the training dataset for training the neural network model; and
generating the mapping dataset in which the plurality of feature combinations are respectively mapped to the plurality of configuration files.

4. The method of claim 3, wherein converting the preset data into the graph includes:
converting, based on first information and second information, each component of a plurality of components included in each standard cell of the plurality of standard cells into a plurality of node features represented by a vector, respectively, and
converting a connection relationship between the plurality of components into an adjacency matrix,
wherein the first information indicates each component of the plurality of components is a port, a net, a transistor, or a transistor pin, and
wherein the second information indicates (i) a port type based on each component of the plurality of components being a port, (ii) a transistor type based on each component of the plurality of components being a transistor, or (iii) a transistor pin type based on each component of the plurality of components being a transistor pin.

5. The method of claim 3, wherein during generating the mapping dataset,
based on a plurality of configuration files corresponding to a portion of the plurality of feature combinations, the mapping dataset is corrected so that a configuration file of the plurality of configuration files corresponds to the portion of the plurality of feature combinations.

6. The method of claim 1, wherein training the neural network model comprises:
executing the neural network model to classify a plurality of features of a plurality of standard cells into a plurality of groups, and
selecting a single configuration file for the plurality of features classified into a group of the plurality of groups.

7. The method of claim 1, wherein extracting the plurality of features of the target standard cell comprises:
executing the neural network model to extract the plurality of feature combinations, each feature combination of the plurality of feature combinations including two or more different features.

8. The method of claim 7, wherein each feature combination of the plurality of feature combinations includes two or more of a topological structure, function, and timing arc.

9. The method of claim 7, wherein extracting the plurality of features of the target standard cell comprises:
executing the neural network model to extract a first feature combination from a first target standard cell and extract a second feature combination from a second target standard cell, and
wherein selecting the configuration file comprises:
based on a first plurality of features included in the first feature combination matching a second plurality of features included in the second feature combination, selecting a same configuration file for the first feature combination and the second feature combination.

10. The method of claim 7, wherein extracting the plurality of features of the target standard cell comprises:
executing the neural network model to extract a first feature combination from a first target standard cell and extract a second feature combination from a second target standard cell, and
wherein selecting the configuration file comprises:
based on portions of a first plurality of features included in the first feature combination matching a second plurality of features included in the second feature combination, selecting a same configuration file for the first feature combination and the second feature combination.

11. The method of claim 1, wherein selecting the configuration file comprises:
executing the neural network model to select, based on the mapping dataset, the configuration file corresponding to the plurality of feature combinations extracted from the target standard cell.

12. The method of claim 1, wherein the neural network model is at least one of a Graph Neural Network (GNN) model or an Artificial Neural Network (ANN) model.

13. The method of claim 12, wherein the GNN model is at least one of a GraphSAGE model, a Graph Convolutional Network (GCN) model, a Graph Attention Network (GAT) model, or a Graph Isomorphism Network (GIN) model.

14. The method of claim 1, wherein the neural network model includes a Graph Neural Network (GNN) model and a graph transformer model connected in series.

15. The method of claim 1, wherein the target standard cell is included in a Dynamic Random Access Memory (DRAM).

16. The method of claim 1, wherein the target standard cell is included in a non-volatile memory.

17. The method of claim 1, wherein an input terminal or an output terminal of the target standard cell and a transmission gate are directly connected.

18. A method of designing a semiconductor device, comprising:
converting information of a target standard cell into information suitable for input of a neural network model;
extracting, based on the neural network model, a plurality of feature combinations of the target standard cell from the information suitable for input of the neural network model;
selecting, based on the neural network model, a configuration file corresponding to the plurality of feature combinations of the target standard cell; and
applying the configuration file to an Electronic Design Automation (EDA) tool to perform characterization of the target standard cell.

19. A method of designing a semiconductor device, comprising:
converting a plurality of components included in a target standard cell into a plurality of nodes;
representing, as a vector, a plurality of node features included in each node of the plurality of nodes;
representing, as an adjacent matrix, a connection relationship between the plurality of components;
inputting the vector and the adjacency matrix into a neural network model; and
outputting, by the neural network model, a plurality of feature combinations of the target standard cell based on the vector and the adjacent matrix,
wherein the plurality of node features include first information indicating each component of the plurality of components is a port, a net, a transistor, or a transistor pin, and second information indicating (i) a port type based on each component of the plurality of components being a port, (ii) a transistor type based on each component of the plurality of components being a transistor, or (iii) a transistor pin type based on each component of the plurality of components being a transistor pin.

20. The method claim 19, comprising:
selecting a configuration file based on a mapping dataset, wherein the plurality of feature combinations of the target standard cell, a plurality of feature combinations of a plurality of standard cells, and the configuration file are mapped in the mapping dataset;
applying the configuration file to an Electronic Design Automation (EDA) tool to perform characterization of the target standard cell; and
adding the characterized target standard cell to a library.
